(19) United States
(12) Patent Application Publication
(10) Pub. No.: US 2024/0201578 A1
(43) Pub. Date: Jun. 20, 2024

(54) OPTICAL PROXIMITY CORRECTION (OPC) METHOD AND METHOD OF MANUFACTURING MASK BY USING THE SAME

(71) Applicant: SAMSUNG ELECTRONICS CO., LTD., SUWON-SI (KR)

(72) Inventors: Myoungho KANG, SUWON-SI (KR); Yongah KIM, SUWON-SI (KR)

(21) Appl. No.: 18/449,078

(22) Filed: Aug. 14, 2023

(30) Foreign Application Priority Data
Dec. 14, 2022 (KR) 10-2022-0174951

(51) Int. Cl. G03F 1/36; G03F 1/70; G03F 7/00

(52) U.S. Cl. CPC G03F 1/36; G03F 1/70; G03F 7/70441; G03F 7/705

(57) ABSTRACT

An optical proximity correction (OPC) method includes generating a mask layout for target patterns on a wafer, dividing edges of the mask layout into fragments, generating a rotated mask layout by rotating the mask layout at a predetermined angle, extracting a contour of a target pattern by inputting data on the fragments of the rotated mask layout to an OPC model, calculating an edge placement error (EPE) for each fragment, determining whether to re-perform the extracting of the contour of the target pattern, calculating displacements of the fragments when it is determined that the extracting of the contour of the target pattern is re-performed, and moving the fragments by the displacements.

### CROSS-REFERENCE TO RELATED APPLICATION

This application claims priority under 35 U.S.C. § 119 to Korean Patent Application No. 10-2022-0174951, filed on Dec. 14, 2022 in the Korean Intellectual Property Office, the disclosure of which is incorporated by reference herein in its entirety.

### TECHNICAL FIELD

Embodiments of the inventive concept relate to a method of manufacturing a mask, and more particularly, to an optical proximity correction (OPC) method and a method of manufacturing a mask by using the same.

### DISCUSSION OF RELATED ART

In a semiconductor process, a photolithography process using a mask may be performed to form a pattern on a semiconductor substrate, such as a wafer. The mask may be defined as a pattern transfer body in which a pattern shape of an opaque material is formed on a transparent base material. To briefly explain manufacturing processes of the mask, a circuit is first designed, a layout is designed for the circuit, and then design data obtained through OPC is transmitted as mask tape-out (MTO) design data. Then, mask data preparation (MDP) may be performed based on the MTO design data, and an exposure process may be performed on a substrate for a mask.

### SUMMARY

Embodiments of the inventive concept relate to an optical proximity correction (OPC) method capable of simplifying a patterning process and increasing reliability of patterning, and a method of manufacturing a mask by using the same.

According to an embodiment of the inventive concept, an OPC method includes generating a mask layout for target patterns on a wafer, dividing edges of the mask layout into fragments having a same length, generating a rotated mask layout by rotating the mask layout at a predetermined angle, extracting a contour of a target pattern through simulation by inputting data on the fragments of the rotated mask layout to an OPC model, calculating an edge placement error (EPE) that is a difference between the contour and an edge of the target pattern for each fragment, determining whether to re-perform the extracting of the contour of the target pattern, calculating displacements of the fragments when it is determined that the extracting of the contour of the target pattern is re-performed, moving the fragments by the displacements, and repeating the extracting of the contour of the target pattern after moving the fragments by the displacements.

According to an embodiment of the inventive concept, an OPC method includes generating a mask layout with one mask for rectangular target patterns arranged in zigzags on a wafer in a first direction, dividing edges of the mask layout into fragments having a same length, generating a rotated mask layout by rotating the mask layout at an angle at which corners between the mask layout and an adjacent mask layout are farthest apart, extracting a contour of a target pattern through simulation by inputting data on the fragments of the rotated mask layout to an OPC model, calculating an edge placement error (EPE) that is a difference between the contour and an edge of the target pattern for each fragment, and determining whether to re-perform the extracting of the contour of the target pattern based on a set reference value or a set reference number of times for the EPE. When it is determined to re-perform the extracting of the contour of the target pattern, the OPC method further includes calculating displacements of the fragments, moving the fragments by the displacements, and repeating the extracting of the contour of the target pattern after moving the fragments by the displacements. When it is determined not to re-perform the extracting of the contour of the target pattern, the OPC method further includes determining the rotated mask layout as an OPCed layout.

According to an embodiment of the inventive concept, a mask manufacturing method includes generating a mask layout with one mask for target patterns arranged in zigzags on a wafer in a first direction, dividing edges of the mask layout into fragments having a same length, generating a rotated mask layout by rotating the mask layout at a predetermined angle, extracting a contour of a target pattern through simulation by inputting data on the fragments of the rotated mask layout to an OPC model, calculating an edge placement error (EPE) that is a difference between the contour and an edge of the target pattern for each fragment, and determining whether to re-perform the extracting of the contour of the target pattern. When it is determined not to re-perform the extracting of the contour of the target pattern, the method further includes determining the rotated mask layout as an OPCed layout, transmitting data on the OPCed layout as mask tape-out (MTO) design data, preparing mask data based on the MTO design data, and performing exposure on a substrate for a mask based on the mask data. When it is determined to re-perform the extracting of the contour of the target pattern, the method further includes calculating displacements of the fragments, moving the fragments by the displacements, and repeating the extracting of the contour of the target pattern after moving the fragments by the displacements.

### BRIEF DESCRIPTION OF THE DRAWINGS

The above and other features of the inventive concept will become more apparent by describing in detail embodiments thereof with reference to the accompanying drawings, in which:

FIG. 1 is a flowchart schematically illustrating processes of an optical proximity correction (OPC) method according to an embodiment;

FIG. 2 is a flowchart schematically illustrating processes of an OPC method according to an embodiment;

FIGS. 3A to 3F are conceptual diagrams illustrating processes of the OPC method of FIG. 2;

FIGS. 4A and 4B are conceptual diagrams illustrating a rotation angle in a process of rotating a mask layout of the OPC method of FIG. 2;

FIG. 5 is a conceptual diagram referred to in describing a concept of a corner rounding radius (CRR) in the OPC method of FIG. 2;

FIGS. 6A and 6B are plan views illustrating an OPCed layout generated by an OPC method of a comparative example and an OPCed layout generated by an OPC method according to an embodiment;

FIGS. 7A and 7B are scanning electron microscope (SEM) photographs of after development inspection (ADI) after an exposure process using the OPCed layouts of FIGS. 6A and 6B;

FIG. 8 is a plan view illustrating the OPCed layouts of FIG. 6B in an entire mask; and

FIG. 9 is a flowchart schematically illustrating processes of a mask manufacturing method using an OPC method according to an embodiment.

### DETAILED DESCRIPTION OF THE EMBODIMENTS

Hereinafter, embodiments of the inventive concept will be described in detail with reference to the accompanying drawings. Like reference numerals may refer to like elements throughout the accompanying drawings, and repetitive descriptions may be omitted for convenience of explanation.

It will be understood that the terms “first,” “second,” “third,” etc. are used herein to distinguish one element from another, and the elements are not limited by these terms. Thus, a “first” element in an embodiment may be described as a “second” element in another embodiment.

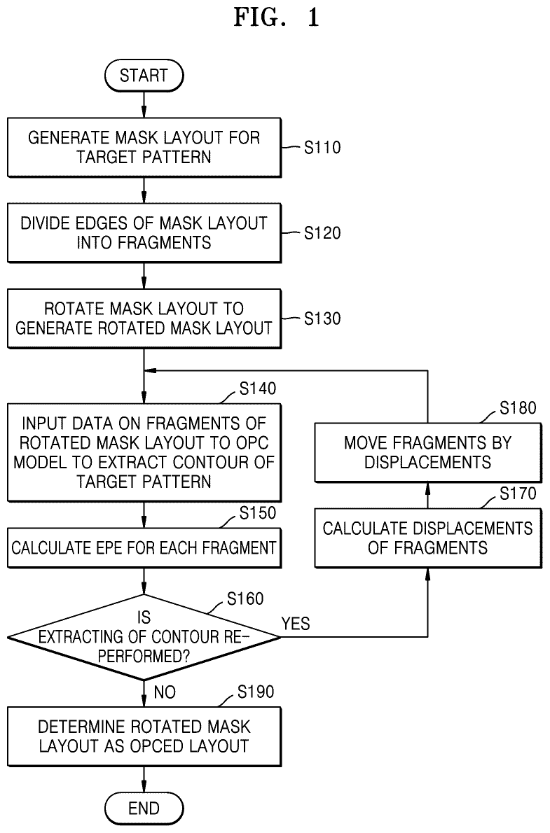

FIG. 1 is a flowchart schematically illustrating processes of an optical proximity correction (OPC) method according to an embodiment.

Referring to FIG. 1, in the OPC method according to an embodiment, first, a mask layout for a target pattern is generated in operation S110. Here, the target pattern may mean a pattern to be formed on a substrate, such as a wafer, through an exposure process using a mask. In addition, the mask layout may mean a layout for a pattern formed on the mask to form the target pattern. In other words, the pattern on the mask may be transferred to the substrate through the exposure process to form the target pattern on the substrate. Due to characteristics of the exposure process, a shape of the target pattern may be generally different from a shape of the mask layout.

On the other hand, in the OPC method according to an embodiment, a mask layout of one mask is generated for target patterns, such as patterns arranged in zigzags, in one direction. For reference, in the case of the patterns arranged in zigzags, mask layouts of two masks are generally generated corresponding to each line and an OPC process is performed to generate a final mask layout for each of the two masks. However, because the final mask layout for each of the two masks is generated and the exposure process is performed by using the two masks to form the patterns arranged in zigzags, time and cost of a patterning process may increase.

However, in the OPC method according to an embodiment, a mask layout of one mask is generated for target patterns utilizing two or more masks, such as the patterns arranged in zigzags. In addition, the following processes described hereinafter are performed to generate a final mask layout, that is, an OPCed mask layout, for one mask.

Next, edges of the mask layout are divided into fragments in operation S120. The fragments may mean straight line segments respectively corresponding to the edges of the mask layout, or data on the straight line segments. The edges of the mask layout may be divided into a plurality of fragments by a predetermined dividing rule. Lengths of the fragments or the dividing rule may be set by a user performing the OPC method. In the OPC method according to an embodiment, each of the edges of the mask layout may be divided into two fragments having the same length.

For reference, the OPC method refers to a method of suppressing occurrence of optical proximity effect (OPE) by correcting mask layouts of patterns to overcome the OPE caused by an influence between neighboring patterns during the exposure process as the patterns become finer. The OPC method may have two classifications. For example, the OPC method may be classified as a rule-based OPC method, or may be classified as a simulation-based or model-based OPC method. The OPC method according to an embodiment may include, for example, the model-based OPC method. The model-based OPC method may decrease time and cost because the model-based OPC method uses only measurement results of representative patterns without measuring all of a large amount of test patterns.

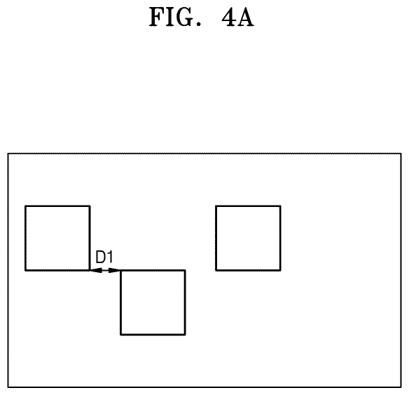

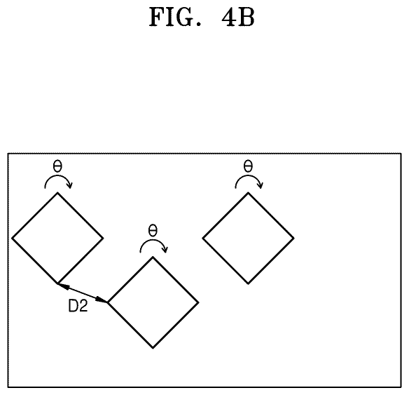

Then, the mask layout is rotated to generate a rotated mask layout in operation S130. The mask layout may be rotated, for example, at an angle at which corners between adjacent mask layouts are farthest apart. The rotation of the mask layout is described in more detail with reference to FIGS. 4A and 4B.

After generating the rotated mask layout, data on the rotated mask layout is input to an OPC model to extract a contour of the target pattern through simulation in operation S140. Here, the data on the rotated mask layout may include data on the fragments.

On the other hand, the OPC model is a simulation model that may be used to extract the contour of the target pattern, and various basic data items may be input to the OPC model as input data. Here, the basic data items may include mask data, for example, data on the fragments of the mask layout. On the other hand, the basic data items may include information data such as, for example, a thickness, a refractive index, and a dielectric constant for photoresist (PR), and may include source map data for a shape of an illumination system. However, the basic data items are not limited to the data exemplified above. On the other hand, the mask data included in the basic data items may include not only fragment data, but also data such as, for example, a shape of patterns, a position of patterns, a type of measurement of patterns (spaces or bars), and basic measurement values.

The contour of the target pattern as a result of simulation using the OPC model may correspond to the shape of the patterns formed on the wafer through the exposure process using the mask. Therefore, the purpose of the OPC method may be to make the contour as similar to the shape of the target pattern as possible.

After extracting the contour of the target pattern, an edge placement error (EPE) is calculated for each fragment in operation S150. The EPE may be calculated by the following equation (1).

$$EPE = target pattern - contour \qquad Equation ( 1 )$$

The EPE may mean a difference between edges of the target pattern and the contour. When the EPE is large, the difference between the contour and the target pattern is large, which may mean that the layout of the corresponding mask is not suitable for forming the target pattern. Therefore, to implement a mask layout suitable for forming the target pattern, embodiments may change the mask layout to reduce the EPE to be less than or equal to a set reference value.

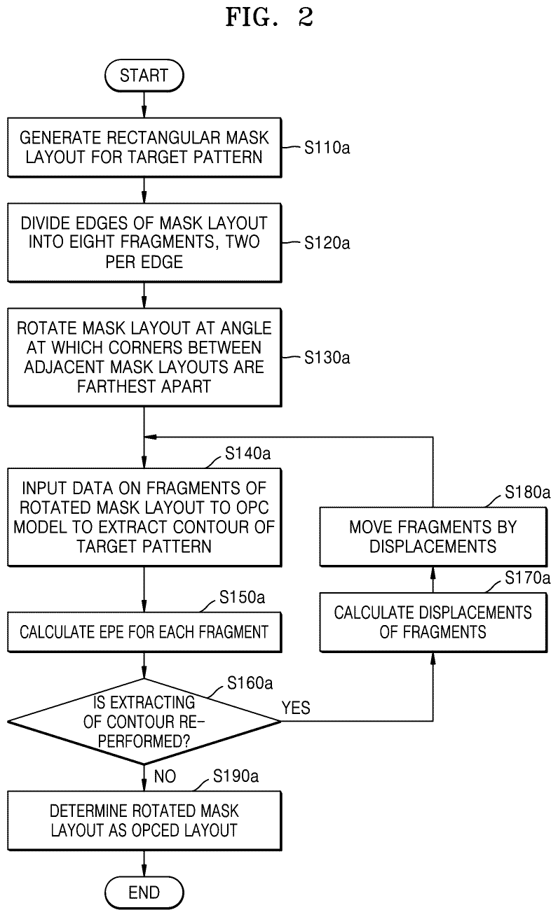

The EPE is calculated for each fragment. When the contour corresponds to a straight edge, the EPE may be obtained as an average of values obtained by subtracting the corresponding contour from the edge of the target pattern for each fragment. On the other hand, when the contour corresponds to a corner, the EPE may be obtained as a maximum value or a minimum value of values obtained by subtracting the contour from a corner position of the target pattern. For example, the maximum value may be obtained as the EPE in a concave corner of the target pattern, and the minimum value may be obtained as the EPE in a convex corner of the target pattern. A process of obtaining the EPE is described in more detail with reference to FIG. 2.

After calculating the EPE, it is determined whether to re-perform operation S140 of extracting the contour of the target pattern in operation S160. For example, depending on whether the calculated EPE is greater than the set reference value, it may be determined whether to further perform the operation of extracting the contour of the target pattern through OPC simulation. For example, when the calculated EPE is greater than the reference value, it may be determined to re-perform operation S140 of extracting the contour of the target pattern, and when the calculated EPE is less than or equal to the reference value, it may be determined not to re-perform operation S140 of extracting the contour of the target pattern.

On the other hand, in an embodiment, whether to re-perform operation S140 of extracting the contour of the target pattern may be determined by comparing the number of times the OPC simulation is performed with a set reference number of times to further perform the process of extracting the contour of the target pattern through the OPC simulation. For example, when the number of times the OPC simulation is performed is less than the reference number of times, it may be determined that operation S140 of extracting the contour of the target pattern is re-performed, and when the number of times the OPC simulation is performed is equal to the reference number of times, it may be determined that operation S140 of extracting the contour of the target pattern is not performed. Here, the reference number of times may be generally set based on an average number of times or the maximum number of times the EPE reaches the reference value through the OPC simulation. In addition, the number of times the OPC simulation is performed may be substantially the same as the number of times operation S140 of extracting the contour of the target pattern is performed.

When it is determined that operation S140 of extracting the contour of the target pattern is re-performed (Yes in operation S160), displacements of fragments are calculated in operation S170. The displacements of the fragments may be obtained so that an average of the EPEs calculated at control points CP is minimized or reduced. In a method of calculating the displacements of the fragments, a feedback factor (FB) may be used. For example, a displacement DIS of a fragment may be calculated as EPE*FB. Here, the FB may be generally greater than −1 and less than +1. However, the numerical value of the FB is not limited thereto. Here, (−) and (+) may mean a movement direction, as the displacement refers to a distance by which the current fragment is moved to the left or right, or up or down, and may be less than an absolute value of the EPE.

When the displacements of the fragments are calculated, the fragments are moved by the displacements in operation S180. The displacements of the fragments correspond to movements of the edges of the mask layout, and may also correspond to a change in shape of the mask layout.

Then, the process returns to operation S140 of extracting the contour of the target pattern, and the contour of the target pattern is extracted again through the OPC simulation. In the OPC model, data on the fragments previously moved by the calculated displacements may be input as the mask data of the basic data items.

When it is determined that operation S140 of extracting the contour of the target pattern is not re-performed (No in operation S160), the rotated mask layout is determined as an OPCed layout in operation S190. Here, the rotated mask layout may correspond to a final rotated mask layout in which the EPE is minimized or reduced by repeating operations S140 to S180 several times to move the fragments.

In general, the EPE obtained by extracting the contour of the target pattern through the OPC simulation at first and calculating the EPE may deviate remarkably from the reference value. Therefore, in general, after performing the OPC simulation several to dozens of times, it may be determined that the OPC simulation is not performed. As a result, the rotated mask layout, including data on the final fragment moved by performing the OPC simulation a plurality of number of times, may be determined as the OPCed layout.

In the OPC method according to an embodiment, it is possible to implement a mask layout capable of minimizing or reducing an EPE and minimizing or reducing a corner rounding phenomenon without violating a mask rule check (MRC) by generating a mask layout for a target pattern, dividing edges of the mask layout into fragments, rotating the mask layout at a predetermined angle and extracting a contour through OPC simulation to calculate the EPE, and repeating the OPC simulation in accordance with a predetermined reference. In addition, in the OPC method according to an embodiment, it is possible to manufacture an excellent mask capable of excellently forming a target pattern on a wafer by generating a mask layout capable of extracting a contour that almost matches the target pattern through the above process.

For reference, in the case patterns are arranged in zigzags in one direction, when the patterns are formed by using one mask through a general OPC method, it may be difficult to secure normal resolution between adjacent patterns due to limitations of exposure equipment, such as Arf-I exposure equipment, the MRC may be violated, and the corner rounding phenomenon may occur. Here, in Arf-I, I may mean immersion. The MRC may refer to a check for a limit on a width of a pattern or an interval between patterns to be maintained when manufacturing a mask. For example, when manufacturing a mask, there may be a limit that may not make the width of the pattern less than a set minimum width or the interval between the patterns less than a set minimum interval. The MRC may refer to a process of checking whether the limit on the layout of the mask is observed.

The corner rounding phenomenon in which rounding occurs at corners of a pattern in an exposure process due to a resolution limit may act as a major cause of reducing a process margin. On the other hand, because the corner rounding phenomenon is in a trade-off relationship with the MRC, there is a limit to minimize or reduce the corner rounding phenomenon without violating the MRC. In other words, when the OPC method is performed to approximate the target pattern by minimizing or reducing corner rounding, the MRC may be violated. Conversely, when the OPC method is performed so as not to violate the MRC, the corner rounding becomes large and remarkably deviates from the target pattern, resulting in a defect in the OPC method.

However, in the OPC method according to an embodiment, it is possible to generate a mask layout capable of minimizing or reducing an EPE and minimizing or reducing a corner rounding phenomenon without violating the MRC by performing OPC on target patterns arranged in zigzags in one direction through the process described above.

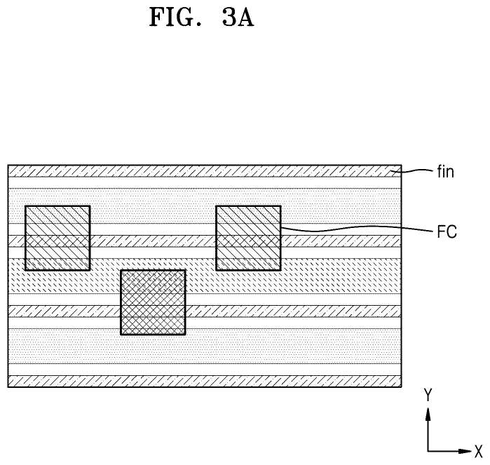

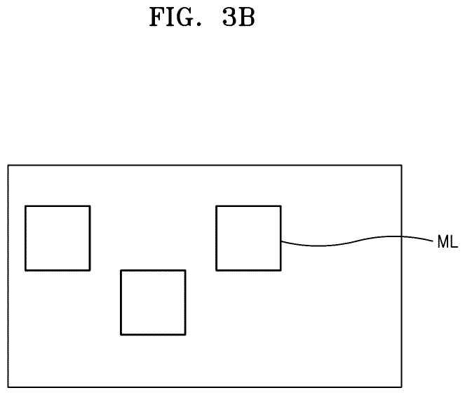

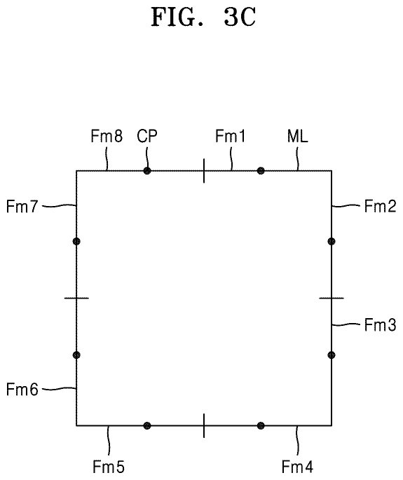

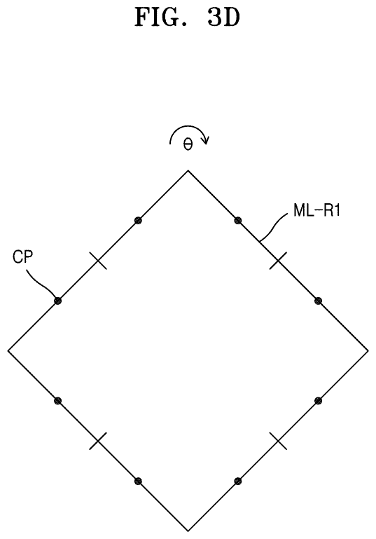

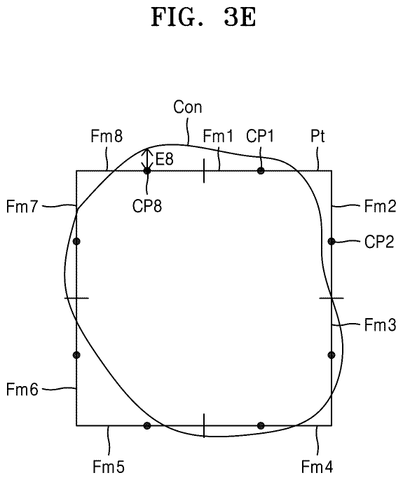

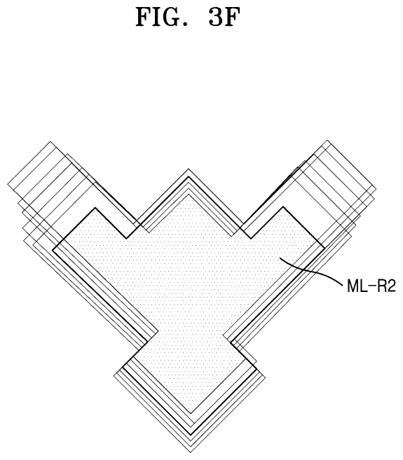

FIG. 2 is a flowchart schematically illustrating processes of an OPC method according to an embodiment, for example, detailed processes of the OPC method for rectangular target patterns. FIGS. 3A to 3F are conceptual diagrams illustrating processes of the OPC method of FIG. 2. For convenience of explanation, a further description of components and technical elements previously described with reference to FIG. 1 may be omitted or only briefly described.

Referring to FIGS. 2, 3A, and 3B, in the OPC method according to an embodiment, first, a rectangular mask layout ML for target patterns FC is generated in operation S110a. As illustrated in FIG. 3A, the target patterns FC may include rectangular patterns arranged in zigzags in an X direction. In addition, for the rectangular patterns arranged in zigzags, a mask layout ML of one mask is generated. In a comparative example, a mask layout of one mask for patterns arranged along an upper line and one mask layout for patterns arranged along a lower line are generated. However, in the OPC method according to an embodiment, the mask layout ML of the one mask is generated. In other words, the mask layout ML of the one mask is generated without distinguishing the patterns of the upper line from the patterns of the lower line.

For reference, FIG. 3A illustrates, for example, a static random access memory (SRAM) device including fins extending in the X direction, and the rectangular target patterns FC may correspond to fin-cut patterns cutting fins among pull-up transistors neighboring in the X direction. In addition, a line having a relatively large width between fins in the Y direction may correspond to dummy fins.

Referring to FIGS. 2 and 3C, next, edges of the mask layout ML are divided into eight fragments FM1 to FM8, two per edge, in operation S120a. For example, one edge may be divided into two fragments so that the two fragments have the same length. For example, an edge of an upper side may be divided into a first fragment Fm1 and an eighth fragment Fm8. The first fragment Fm1 and the eighth fragment Fm8 may have substantially the same length. On the other hand, a control point CP may be set at the center of each of the eight fragments. The control points CP may be used for calculating the EPE and moving the fragments, which is described in more detail with reference to FIG. 3E.

Referring to FIGS. 2 and 3D, then, the mask layout ML is rotated to generate a rotated mask layout ML-R1 in operation S130a. In the OPC method according to an embodiment, the mask layout ML may be rotated at a rotation angle θ at which corners between adjacent mask layouts ML are farthest apart. For example, in the OPC method according to an embodiment, the rotation angle θ of the mask layout ML may be about 45°. However, the rotation angle θ of the mask layout ML is not limited thereto.

Referring to FIG. 2 and FIG. 3E, after generating the rotated mask layout ML-R1, data on the rotated mask layout ML-R1 is input to an OPC model to extract a contour Con of a target pattern Pt through simulation in operation S140a. Here, the data on the rotated mask layout ML-R1 may also include data on the fragments. On the other hand, the target pattern Pt may correspond to a kind of reference and may remain unchanged. For example, the target pattern Pt may correspond to the target pattern FC including the fin-cut pattern of FIG. 3A. On the other hand, a shape of the mask layout ML or the rotated mask layout ML-R1 continues to change due to movement of the fragments.

Subsequently, after extracting the contour Con of the target pattern Pt, an EPE is calculated for each fragment in operation S150a. The EPE may be calculated by the equation (1) above. The EPE is calculated for each fragment. When the contour Con corresponds to a straight edge, the EPE may be obtained as an average of values obtained by subtracting the contour Con from the edge of the target pattern Pt for each fragment. For example, in the case of the edge of the target pattern Pt corresponding to the eighth fragment Fm8, the EPE E8 may be calculated at an eighth control point CP8. Then, in operation S180a of calculating displacements of the fragments, the displacements of the fragments are calculated so that an average of the EPEs calculated at the control points CP is minimized or reduced.

On the other hand, when the contour Con corresponds to a corner, the EPE may be obtained as a maximum value or a minimum value of a value obtained by subtracting the contour Con from a corner position of the target pattern Pt. For example, as illustrated in FIG. 3E, at the convex corner of the rectangular target pattern Pt, the minimum value may be obtained as the EPE.

After calculating the EPE, it is determined whether to re-perform operation S140a of extracting the contour of the target pattern in operation S160a. For example, depending on whether the calculated EPE is greater than the set reference value or whether the number of times the OPC simulation is performed reaches the set reference number of times, it may be determined whether to further perform the process of extracting the contour of the target pattern through the OPC simulation. Here, the calculated EPE may mean an average of the EPEs calculated at the control points CP.

Referring to FIGS. 2 and 3F, when it is determined that operation S140a of extracting the contour of the target pattern is re-performed (Yes in operation S160a), the displacements of the fragments are calculated in operation S170a. As described above, the displacements of the fragments may be obtained so that an average of the EPEs calculated at the control points CP is minimized or reduced. In addition, the displacements of the fragments may be obtained by using, for example, the FB.

When the displacements of the fragments are calculated, the fragments are moved by the displacements in operation S180a. The movement of the fragments corresponds to the movement of the edges of the mask layout, and may also correspond to a change in shape of the mask layout. Then, the process returns to operation S140a of extracting the contour of the target pattern, and the contour of the target pattern is extracted again through the OPC simulation. Such a process is repeated until the calculated EPE is less than or equal to the set reference value or the number of times the OPC simulation is performed reaches the set reference number of times.

FIG. 3F schematically illustrates a process in which the rotated mask layout ML-R1 becomes the final rotated mask layout ML-R2 by repeating operations S140a to S180a. In FIG. 3F, thin solid lines represent the edges of the fluctuating mask layout, and a hatched portion may correspond to the final rotated mask layout ML-R2.

When it is determined that operation S140a of extracting the contour of the target pattern is not re-performed (No in operation S160a), the final rotated mask layout is determined as the OPCed layout in operation S190a.

FIGS. 4A and 4B are conceptual diagrams illustrating a rotation angle in a process of rotating a mask layout of the OPC method of FIG. 2.

Referring to FIG. 4A, a first distance D1 between corners of adjacent mask layouts before rotation is very small so that, when a pattern is to be implemented with one mask, a resolution limit of exposure equipment, a mark rule check (MRC) issue, or a corner rounding phenomenon, may occur.

Referring to FIG. 4B, when the mask layouts are rotated, a second distance D2 between the corners of the adjacent mask layouts is greater than the first distance D1. Therefore, when the second distance D2 is large enough to solve the resolution limit of the exposure equipment, the MRC issue, or the corner rounding phenomenon, the pattern may be sufficiently implemented with one mask. When a pattern is implemented with one mask, the time and cost of the patterning process may be greatly reduced.

On the other hand, the rotation angle θ of the mask layout may be optimal at an angle at which corners between adjacent mask layouts are farthest apart. For example, in the case of the patterns arranged in zigzags as illustrated in FIG. 4A, for example, the optimal rotation angle θ may be about 45°. However, depending on a shape in which the patterns are arranged, the optimal rotation angle θ may vary.

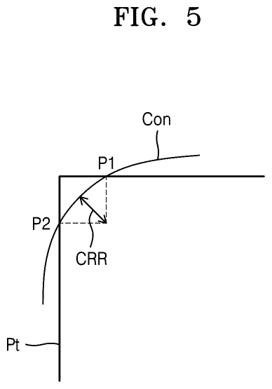

FIG. 5 is a conceptual diagram referred to in describing a concept of a corner rounding radius (CRR) in the OPC method of FIG. 2.

Referring to FIG. 5, when describing the corner rounding phenomenon, the CRR may be generally defined. For example, the CRR may be defined by points P1 and P2 at which the contour Con first meets the target pattern Pt from the corner position of the target pattern Pt. When the CRR is large, the corner rounding phenomenon is referred to as being large, and when the CRR is small, the corner rounding phenomenon is referred to as being small. On the other hand, as described above, because the corner rounding phenomenon is in the trade-off relationship with the MRC, the CRR may increase when the MRC is strictly followed. Therefore, the CRR is optimized in consideration of the MRC in embodiments. Optimization of the CRR is also referred to as optimization of a corner-lining EPE. Herein, optimization may also refer to improvement.

Referring back to FIG. 2, in the OPC method according to an embodiment, in operation S170a of calculating the displacements of the fragments, to optimize the CRR, the displacements of the fragments may be calculated so that paired EPEs calculated at two control points adjacent to each corner are minimized or reduced. For example, referring to FIG. 3E, the CRR may be optimized by calculating the displacements of the fragments so that the paired EPEs calculated at a first control point CP1 and a second control point CP2 adjacent to the upper right corner have minimum or reduced values. In FIG. 3F, to optimize the CRR, it may be noted that the fragments adjacent to the corner are moved together in pairs.

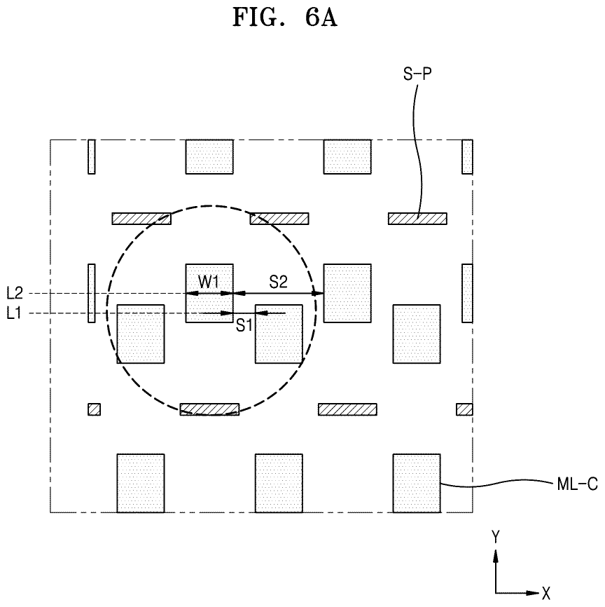

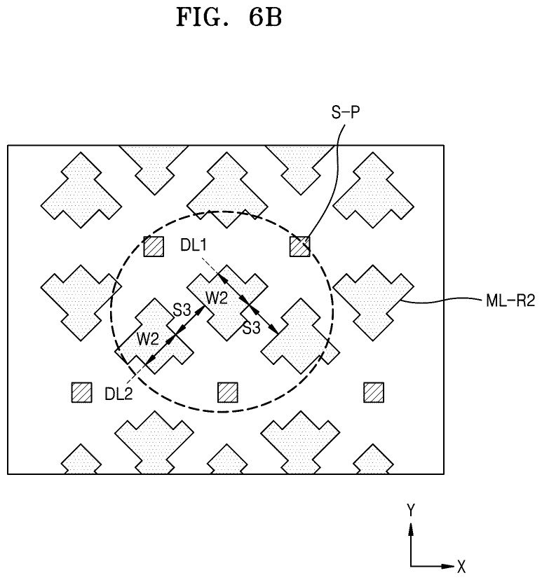

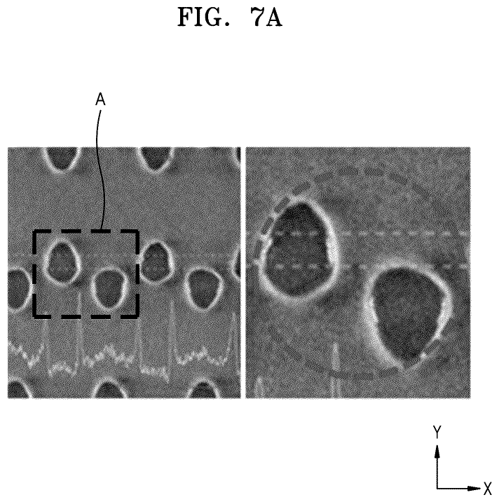

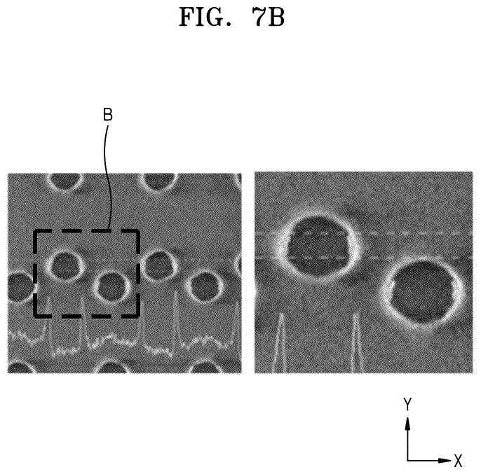

FIGS. 6A and 6B are plan views illustrating an OPCed layout ML-C generated by an OPC method of a comparative example and an OPCed layout ML-R2 generated by an OPC method according to an embodiment. FIGS. 7A and 7B are scanning electron microscope (SEM) photographs of after development inspection (ADI) after an exposure process using the OPCed layouts of FIGS. 6A and 6B. The right SEM image of FIG. 7A illustrates an enlarged portion A of the left SEM image, and the right SEM image of FIG. 7B illustrates an enlarged portion B of the left SEM image.

Referring to FIGS. 6A and 7A, the OPCed layout ML-C generated by the OPC method of the comparative example is illustrated for the patterns arranged in zigzags, which are illustrated in FIG. 3A. In the OPC method of the comparative example, a mask layout of one mask is generated, but a final mask layout, that is, the OPCed layout ML-C, is generated through a general OPC method. The OPCed layout ML-C generated by the OPC method of the comparative example may have two pitches for one pattern as illustrated in FIG. 6A. In FIG. 6A, small patterns S-P may correspond to sub-resolution patterns.

When a pattern is referred to as a bar and an interval between patterns is referred to as a space, one bar may be spaced apart from a neighboring bar by a first space S1 in a lower line L1 and may be spaced apart from a neighboring bar by a second space S2 in an upper line L2. Therefore, when the bar has a first width W1, the bar may have a first pitch W1+S1 in the lower line L1 and a second pitch W1+S2 in the upper line L2.

On the other hand, in a portion corresponding to the first pitch, the first space S1 may be much less than the first width W1 of the bar. Accordingly, when a mask is manufactured by using the OPCed layout ML-C generated by the OPC method of the comparative example and an exposure process is performed, a pattern defect may occur as illustrated in FIG. 7A. For example, a pattern formed through the exposure process may not have a uniform width and may have a distorted shape in which a width in the X direction of an upper or lower portion is small. When the pattern has a distorted shape, a process margin may decrease in relation to a lower layer. For example, assuming that a portion marked with two dashed lines corresponds to a fin to be cut, when the pattern has a distorted shape, a critical dimension (CD) of a cut portion may remarkably vary as the pattern moves in the Y direction.

Referring to FIGS. 6B and 7B, the OPCed layout ML-R2 generated by the OPC method according to an embodiment is illustrated for the patterns arranged in zigzags, which are illustrated in FIG. 3A. In the OPC method according to an embodiment, a mask layout of one mask is generated, edges of the mask layout are divided into fragments, the mask layout is rotated by a predetermined angle to generate a rotated mask layout, and a contour of the rotated mask layout is extracted through OPC simulation. As described above, in the OPCed layout ML-R2 generated by the OPC method according to an embodiment, only one pitch may be provided for one pattern. In addition, in a diagonal direction, widths of patterns and intervals among the patterns may be substantially the same. In FIG. 6B, small patterns S-P may correspond to sub-resolution patterns.

When a pattern is referred to as a bar and an interval between patterns is referred to as a space, one bar may be spaced apart from a neighboring bar by a third space S3 in a first diagonal line DL1 and may be spaced apart from a neighboring bar by the third space S3 in a second diagonal line DL2. Therefore, when the bar has a second width W2, the bar may have a third pitch W2+S3 in the first diagonal line DL1, and may have the third pitch W2+S3 in the second diagonal line DL2. In addition, the second width W2 and the third space S3 may be substantially the same. However, according to an embodiment, the second width W2 and the third space S3 may be different from each other.

Therefore, in the OPCed layout ML-R2 generated by the OPC method according to an embodiment, the first diagonal line DL1 and the second diagonal line DL2 may have the same pitch in either direction. In addition, the third space S3 between the bars may remarkably increase compared to the first space S1 between the bars of the OPCed layout ML-C generated by the OPC method of the comparative example. Accordingly, when a mask is manufactured by using the OPCed layout ML-R2 generated by the OPC method according to an embodiment and an exposure process is performed, a pattern with a uniform shape may be formed as illustrated in FIG. 7A. For example, a pattern formed through the exposure process may have a uniform shape in which a width in the X direction of an upper or lower portion is uniform. Based on uniformity of the pattern, the process margin may greatly increase in relation to the lower layer.

In addition, as illustrated in FIG. 6B, the OPCed layout ML-R2 generated by the OPC method according to an embodiment may have a left-right symmetric triangular shape as a whole. Therefore, the OPCed layout ML-R2 generated by the OPC method according to an embodiment may be referred to as a symmetric triangle (ST)-layout, or an ST-mask shape. In addition, the process of generating the OPCed layout in the form of the ST-layout may be referred to as an ST-OPC method.

The application of the OPC method according to an embodiment to the patterns arranged in zigzags has been described above. However, patterns to which the OPC method according to an embodiment is applied are not limited to the patterns arranged in zigzags. For example, the OPC method according to an embodiment may also be applied to other patterns that are difficult to implement with one mask due to positions and an interval between adjacent patterns in spite of having substantially the same shape.

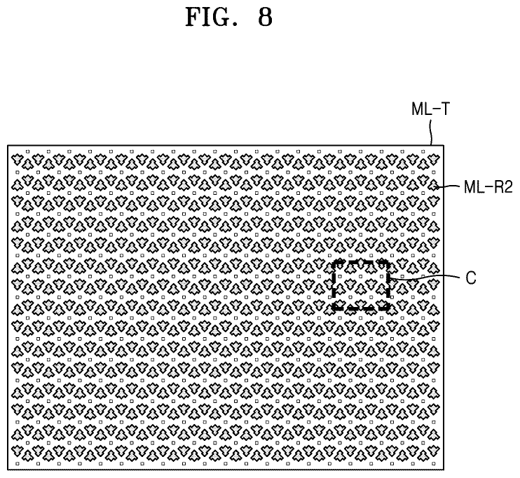

FIG. 8 is a plan view illustrating the OPCed layouts of FIG. 6B in an entire mask ML-T.

Referring to FIG. 8, the OPCed layouts generated with reference to FIGS. 2 to 3F are arranged in a two-dimensional array structure in the entire mask ML-T. For example, an enlarged portion of the portion C of FIG. 8 may correspond to FIG. 6B. The OPCed layouts arranged in the entire mask ML-T may include ST-OPC layouts. Therefore, the pitches of the patterns in the diagonal direction are all substantially the same, and the space between the patterns may be sufficiently maintained. Therefore, as the MRC and the corner rounding phenomenon are optimized, the resolution limit of the exposure equipment, for example, Arf-I exposure equipment, may be sufficiently overcome.

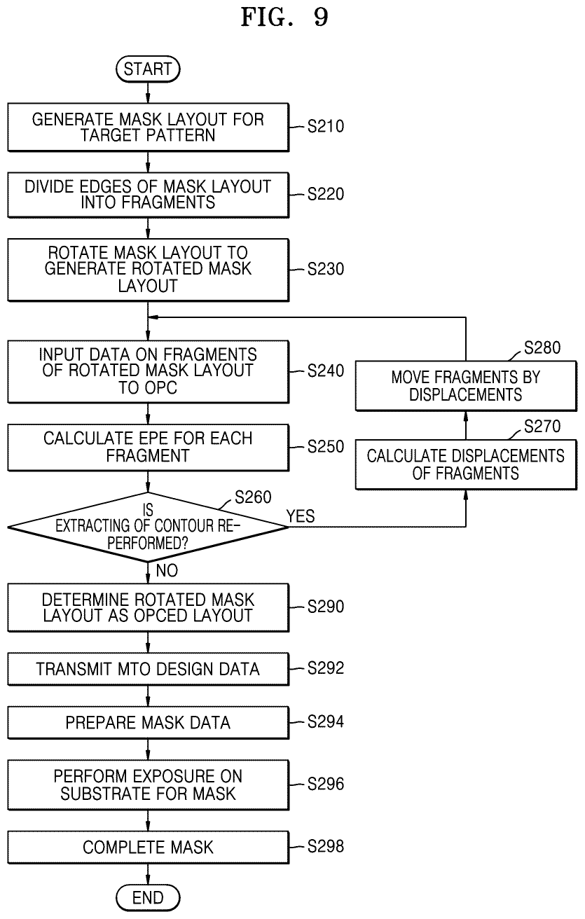

FIG. 9 is a flowchart schematically illustrating processes of a mask manufacturing method using an OPC method according to an embodiment. For convenience of explanation, a further description of components and technical aspects previously described with reference to FIGS. 1 to 8 may be omitted or only briefly described.

Referring to FIG. 9, in the mask manufacturing method using the OPC method (hereinafter, simply referred to as ‘the mask manufacturing method’) according to an embodiment, the OPC method is first performed. The OPC method may include operation S210 of generating a mask layout for a target pattern to operation S290 of determining a rotated mask layout as an OPCed layout. In the mask manufacturing method according to an embodiment, the OPC method may include, for example, the ST-OPC method. Accordingly, the OPC method may include the OPC method of FIG. 1 or 2. For example, operation S210 of generating the mask layout for the target pattern to operation S290 of determining the rotated mask layout as the OPCed layout may correspond to operation S110 of generating the mask layout for the target pattern to the operation S190 of determining the rotated mask layout as the OPCed layout of the OPC method of FIG. 1, or operation S110a of generating the rectangular mask layout for the target to operation S190a of determining the rotated mask layout as the OPCed layout of the OPC method of FIG. 2. Therefore, for convenience of explanation, in the mask manufacturing method according to an embodiment, a further description of operations S210, S220, S230, S240, S250, S260, S270, S280 and S290 of the OPC method is omitted.

After performing the OPC method, the MTO design data is transmitted to a mask manufacturing team in operation S292. In general, the MTO may mean passing data on the final mask layout obtained through the OPC method to the mask manufacturing team to request mask manufacturing. Therefore, in the mask manufacturing method according to an embodiment, the MTO design data may be substantially the same as the OPCed layout image obtained through the OPC method, that is, data on the final rotated mask layout. The MTO design data may have a graphic data format used in, for example, electronic design automation (EDA) software, etc. For example, the MTO design data may have a data format, such as graphic data system II (GDSII) and open artwork system interchange standard (OASIS).

Then, the MDP is performed in operation S294. The MDP may include, for example, i) format conversion called fracturing, ii) augmentation such as a barcode for machine reading, a standard mask pattern for inspection, or a job deck, and iii) verification of automatic and manual methods. Here, the job deck may mean creating a text file for a series of commands, such as, for example, arrangement information of multiple mask files, a reference dose, and an exposure speed or method.

The format conversion, that is, fracturing, may mean a process of dividing the MTO design data by region and changing the MTO design data to a format for an electron beam exposure device. Fracturing may include, for example, data manipulation, such as scaling, data sizing, data rotation, pattern reflection, and color inversion. In the conversion process through fracturing, data on numerous systematic errors that may occur anywhere during transfer from design data to an image on a wafer may be corrected.

The data correction process for the systematic errors is called mask process correction (MPC), and may include, for example, line width adjustment called CD adjustment and increasing pattern placement precision. Accordingly, the fracturing may contribute to improving quality of a final mask and may also be a pre-performed process for MPC. Here, the systematic errors may be caused by distortions occurring in, for example, an exposure process, a mask development and etching process, and a wafer imaging process.

On the other hand, the MDP may include the MPC. The MPC refers to a process of correcting errors occurring during the exposure process, that is, the systematic errors as described above. Here, the exposure process may be a concept generally including, for example, electron beam writing, developing, etching, and baking. In addition, data processing may be performed before the exposure process. The data processing as a kind of pre-processing process for mask data and may include grammar checks for mask data and exposure time prediction.

After preparing the mask data, the substrate for the mask is exposed based on the mask data in operation S296. Here, exposure may mean, for example, electron beam writing. Here, the electron beam writing may be performed by, for example, a gray writing method using a multi-beam mask writer (MBMW). In addition, the electron beam writing may be performed by using a variable shape beam (VSB) exposure device.

On the other hand, after the MDP is performed, a process of converting the mask data into pixel data may be performed before the exposure process. The pixel data directly used for actual exposure may include data on a shape to be exposed and data on an allocated dose. Here, the data on the shape may include bit-map data in which shape data that is vector data is converted through rasterization.

After the exposure process, a series of processes are performed to complete the mask in operation S298. The series of processes may include, for example, processes, such as development, etching, and cleaning. In addition, a series of processes for manufacturing a mask may include a measurement process and a defect inspection or defect repair process. Furthermore, the series of processes for manufacturing the mask may include a pellicle application process. Here, the pellicle application process may mean a process of attaching a pellicle to a mask surface to protect the mask from subsequent contamination during a delivery and service life of the mask when it is confirmed that there are no contaminant particles or chemical stains through final cleaning and inspection.

In the mask manufacturing method according to an embodiment, the OPC method may correspond to the ST-OPC method. For example, in the ST-OPC method, the ST-layout may be generated by rotating the mask layout to generate the rotated mask layout and performing the OPC process. In the ST-layout, the pitches of the patterns in the diagonal direction are all the same, or the space between the patterns may be maintained sufficient. Therefore, in the mask manufacturing method according to an embodiment, as the MRC and the corner rounding phenomenon are optimized, the resolution limit of the exposure equipment may be overcome so that a reliable mask may be manufactured. In addition, by using one mask, the time and cost of the patterning process may be remarkably reduced.

While the inventive concept has been particularly shown and described with reference to embodiments thereof, it will be understood that various changes in form and detail may be made therein without departing from the spirit and scope of the inventive concept as defined by the following claims.

1. An optical proximity correction (OPC) method, comprising:
generating a mask layout for target patterns on a wafer;
dividing edges of the mask layout into fragments having a same length;
generating a rotated mask layout by rotating the mask layout at a predetermined angle;
extracting a contour of a target pattern through simulation by inputting data on the fragments of the rotated mask layout to an OPC model;
calculating an edge placement error (EPE) that is a difference between the contour and an edge of the target pattern for each fragment;
determining whether to re-perform the extracting of the contour of the target pattern;
calculating displacements of the fragments when it is determined that the extracting of the contour of the target pattern is re-performed;
moving the fragments by the displacements; and
repeating the extracting of the contour of the target pattern after moving the fragments by the displacements.

2. The OPC method of claim 1, wherein the target patterns on the wafer are arranged in zigzags in one direction, and
wherein the mask layout is generated as a layout for one mask.

3. The OPC method of claim 1, wherein the mask layout is rectangular,
wherein dividing the edges of the mask layout into the fragments comprises dividing the edges into eight fragments, two per edge, and
wherein a control point is set in a center of each of the fragments.

4. The OPC method of claim 3, wherein generating the rotated mask layout comprises rotating the mask layout at an angle at which corners between the mask layout and an adjacent mask layout are farthest apart.

5. The OPC method of claim 3, wherein the displacements of the fragments are calculated such that an average of EPEs calculated at the control points has a reduced value.

6. The OPC method of claim 3, wherein, when a distance from a position of a corner to a point adjacent to the corner, at which the contour meets an edge of the target pattern, is defined as a corner rounding radius (CRR), the displacements of the fragments are calculated such that paired EPEs calculated at two control points adjacent to each corner are reduced.

7. The OPC method of claim 1, wherein determining whether to re-perform the extracting of the contour of the target pattern is based on whether the EPE is less than or equal to a set reference value or a number of times the extracting of the contour is performed is the same as a reference number of times.

8. The OPC method of claim 1, wherein the target patterns correspond to fin-cut patterns of static random access memory (SRAM),
wherein fins of the SRAM extend in a first direction and are spaced apart from one another in a second direction perpendicular to the first direction, and
wherein the fin-cut patterns are arranged in zigzags in the first direction among fins neighboring in the second direction.

9. The OPC method of claim 1, when it is determined not to re-perform the extracting of the contour of the target pattern, the method further comprises determining the rotated mask layout as an OPCed layout.

10. (canceled)

11. An optical proximity correction (OPC) method, comprising:
generating a mask layout with one mask for rectangular target patterns arranged in zigzags on a wafer in a first direction;
dividing edges of the mask layout into fragments having a same length;
generating a rotated mask layout by rotating the mask layout at an angle at which corners between the mask layout and an adjacent mask layout are farthest apart;
extracting a contour of a target pattern through simulation by inputting data on the fragments of the rotated mask layout to an OPC model;
calculating an edge placement error (EPE) that is a difference between the contour and an edge of the target pattern for each fragment; and
determining whether to re-perform the extracting of the contour of the target pattern based on a set reference value for the EPE or a set reference number of times, wherein, when it is determined to re-perform the extracting of the contour of the target pattern, the method further comprises:
calculating displacements of the fragments;
moving the fragments by the displacements; and
repeating the extracting of the contour of the target pattern after moving the fragments by the displacements,
wherein, when it is determined not to re-perform the extracting of the contour of the target pattern, the method further comprises determining the rotated mask layout as an OPCed layout.

12. The OPC method of claim 11, wherein the mask layout is rectangular,
wherein dividing the edges of the mask layout into the fragments comprises dividing the edges into eight fragments, two per edge, and
wherein a control point is set in a center of each of the fragments.

13. The OPC method of claim 12, wherein the displacements of the fragments are calculated such that an average of EPEs calculated at the control points has a reduced value.

14. (canceled)

15. The OPC method of claim 11, wherein it is determined to re-perform the extracting of the contour of the target pattern when the EPE is less than or equal to the reference value or a number of times the extracting of the contour is performed is the same as the reference number of times, and
wherein it is determined not to re-perform the extracting of the contour of the target pattern when the EPE is greater than the reference value or the number of times the extracting of the contour is performed is less than the reference number of times.

16. (canceled)

17. The OPC method of claim 11, wherein the OPCed layout is a symmetric triangle layout, and
wherein the symmetric triangle layout has one pitch in a rotation direction.

18. A mask manufacturing method, comprising:
generating a mask layout with one mask for target patterns arranged in zigzags on a wafer in a first direction;
dividing edges of the mask layout into fragments having a same length;
generating a rotated mask layout by rotating the mask layout at a predetermined angle;
extracting a contour of a target pattern through simulation by inputting data on the fragments of the rotated mask layout to an optical proximity correction (OPC) model;
calculating an edge placement error (EPE) that is a difference between the contour and an edge of the target pattern for each fragment; and
determining whether to re-perform the extracting of the contour of the target pattern, wherein, when it is determined not to re-perform the extracting of the contour of the target pattern, the method further comprises:
determining the rotated mask layout as an OPCed layout;
transmitting data on the OPCed layout as mask tape-out (MTO) design data;
preparing mask data based on the MTO design data; and
performing exposure on a substrate for a mask based on the mask data, wherein, when it is determined to re-perform the extracting of the contour of the target pattern, the method further comprises:
calculating displacements of the fragments; and
moving the fragments by the displacements; and
repeating the extracting of the contour of the target pattern after moving the fragments by the displacements.

19. The mask manufacturing method of claim 18, wherein the mask layout is rectangular,
wherein dividing the edges of the mask layout into the fragments comprises dividing the edges into eight fragments, two per edge, and
wherein a control point is set in a center of each of the fragments.

20. The mask manufacturing method of claim 19, wherein generating the rotated mask layout comprises rotating the mask layout at an angle at which corners between the mask layout and an adjacent mask layout are farthest apart.

21. The mask manufacturing method of claim 19, wherein the displacements of the fragments are calculated such that an average of EPEs calculated at the control points has a reduced value.

22. The mask manufacturing method of claim 19, wherein, when a distance from a position of a corner to a point adjacent to the corner, at which the contour meets an edge of the target pattern, is defined as a corner rounding radius (CRR), the displacements of the fragments are calculated such that paired EPEs calculated at two control points adjacent to each corner are reduced.

23. (canceled)

24. The mask manufacturing method of claim 18, wherein the target patterns correspond to fin-cut patterns of static random access memory (SRAM),
wherein fins of the SRAM extend in a first direction and are spaced apart from one another in a second direction perpendicular to the first direction, and
wherein the fin-cut patterns are arranged in zigzags in the first direction among fins neighboring in the second direction.

25. (canceled)
